(19) United States
(12) Patent Application Publication
(10) Pub. No.: US 2011/0298080 A1
(43) Pub. Date: Dec. 8, 2011

(54) METHOD FOR MANUFACTURING THERMOELECTRIC CONVERSION MODULE, AND THERMOELECTRIC CONVERSION MODULE

(75) Inventor: Yuichi Hiroyama, Ibaraki (JP)

(73) Assignee: SUMITOMO CHEMICAL COMPANY, LIMITED, Chuo-ku, Tokyo (JP)

(21) Appl. No.: 13/144,643

(22) PCT Filed: Jan. 8, 2010
(86) PCT No.: PCT/JP2010/050161

§ 371 Date: Aug. 25, 2011

(30) Foreign Application Priority Data
Jan. 15, 2009 (JP) 2009-006677

(51) Int. Cl. H01L 29/66; H01L 35/34

(52) U.S. Cl. 257/467; 438/54; 257/E21.24; 257/E29.347

(57) ABSTRACT

There is provided a method for manufacturing a thermoelectric conversion module that can yield a thermoelectric conversion module with a high insulating property and high density without requiring positioning of the thermoelectric conversion elements, as well as a thermoelectric conversion module manufactured by the method. The method for manufacturing a thermoelectric conversion module 1 comprises a covering step of covering, with an insulating film 15, at least faces of the surface of a p-type thermoelectric conversion element 3 other than faces 3a, 3b that are to face electrodes, and/or at least faces of the surface of an n-type thermoelectric conversion element 4 other than faces 4a, 4b that are to face electrodes, and a stacking step of stacking the faces 3a, 3b of the surface of the p-type thermoelectric conversion element 3 other than the faces that are to face the electrodes, and the faces 4a, 4b of the surface of the n-type thermoelectric conversion element other than the faces that are to face the electrodes via the insulating film 15.

### TECHNICAL FIELD

The present invention relates to a method for manufacturing a thermoelectric conversion module, and to a thermoelectric conversion module.

### BACKGROUND ART

One method for manufacturing a module by high densification of a thermoelectric conversion module involves narrowing the width between p-type thermoelectric conversion elements and n-type thermoelectric conversion elements, but this necessitates insulation between the p-type thermoelectric conversion elements and the n-type thermoelectric conversion elements. Patent document 1 discloses a method for manufacturing a module in which an insulating resin is cast into the gaps between pre-positioned p-type thermoelectric conversion elements and n-type thermoelectric conversion elements, for increased insulating reliability.

### CITATION LIST

### Patent literature

[Patent document 1] JP 2003-282972A

### SUMMARY OF INVENTION

### Technical Problem

Positioning of p-type thermoelectric conversion elements and n-type thermoelectric conversion elements, however, is an operation that has complicated the production of thermoelectric conversion modules, due to the small sizes or the like of thermoelectric conversion elements.

It is therefore an object of the present invention to provide a method for manufacturing a thermoelectric conversion module that can yield a thermoelectric conversion module with a high insulating property and high density without requiring positioning of the thermoelectric conversion elements, as well as a thermoelectric conversion module manufactured by the method.

### Solution to Problem

The method for manufacturing a thermoelectric conversion module according to the invention comprises a covering step of covering, with an insulating film, at least faces of the surface of a p-type thermoelectric conversion element other than faces that are to face electrodes, and/or at least faces of the surface of an n-type thermoelectric conversion element other than faces that are to face electrodes, and a step of stacking together the faces of the surfaces of the p-type thermoelectric conversion element other than the faces that are to face the electrodes, and the faces of the surface of the n-type thermoelectric conversion element other than the faces that are to face the electrodes via the insulating film.

According to the invention, at least faces of the surface of a p-type thermoelectric conversion element other than faces that are to face electrodes, and/or at least faces of the surface of an n-type thermoelectric conversion element other than faces that are to face electrodes are covered with an insulating film, while the faces of the surface of the p-type thermoelectric conversion element other than the faces that are to face the electrodes and the faces of the surface of the n-type thermoelectric conversion element other than the faces that are to face the electrodes are stacked together via the insulating film, and therefore it is possible to manufacture a thermoelectric conversion module in which the p-type thermoelectric conversion elements and the n-type thermoelectric conversion elements are insulated by the insulating films, to achieve a high insulating property and high density without positioning.

It is preferable that, in the covering step, the entire surface of the p-type thermoelectric conversion element and/or the entire surface of the n-type thermoelectric conversion element should be covered with the insulating film, and the method should further comprise an insulating film removal step of removing the insulating film by subjecting the p-type thermoelectric conversion element and the n-type thermoelectric conversion element stacked in the stacking step to grind of the faces of the surface of the p-type thermoelectric conversion element that are to face the electrodes and/or the faces of the surface of the n-type thermoelectric conversion element that are to face the electrodes.

According to the invention, the entire surface of the p-type thermoelectric conversion element and/or the entire surface of the n-type thermoelectric conversion element are covered with an insulating film, and therefore the step of covering the surface of the thermoelectric conversion element with the insulating film is convenient in that, for example, it is sufficient to simply dip the p-type thermoelectric conversion element and/or the n-type thermoelectric conversion element into a composition for forming the insulating film. Furthermore, the step of removing the insulating film from the faces of the surface of the p-type thermoelectric conversion element that are to face the electrodes and/or the faces of the surface of the n-type thermoelectric conversion element that are to face the electrodes, in the p-type thermoelectric conversion element and the n-type thermoelectric conversion element stacked via the insulating film, is also relatively convenient since the faces of each thermoelectric conversion element that are to face electrodes are ground once to remove the insulating film. Consequently, the step is simplified overall, compared to selectively forming the insulating film only on parts of the surface of each thermoelectric conversion element so that the faces that are to face the electrode may not be covered by the insulating film.

It is preferable that, prior to the insulating film removal step, the method should comprise a step of integrally anchoring the p-type thermoelectric conversion element and the n-type thermoelectric conversion element stacked in the stacking step to obtain a thermoelectric conversion block.

By integrally anchoring the p-type thermoelectric conversion element and the n-type thermoelectric conversion element that have been stacked via the insulating film to form a thermoelectric conversion block, the stacked p-type thermoelectric conversion element and the n-type thermoelectric conversion element become sufficiently anchored. This will allow grind following this step to be easily accomplished, for removing the insulating film on the faces of the surface of the p-type thermoelectric conversion element that are to face the electrodes and/or the faces of the surface of the n-type thermoelectric conversion element electrode that are to face the electrodes. It will also facilitate bonding of the electrodes to the thermoelectric conversion block.

The thermoelectric conversion module of the invention comprises a p-type thermoelectric conversion element, an n-type thermoelectric conversion element, electrodes that electrically connect the p-type thermoelectric conversion element to the n-type thermoelectric conversion element, an insulating film covering the faces of the surface of the p-type thermoelectric conversion elements other than the faces that are to face the electrodes, and an insulating film covering the faces of the surface of the n-type thermoelectric conversion element other than the faces that are to face the electrodes, and the p-type thermoelectric conversion element and the n-type thermoelectric conversion element are stacked via the two insulating films.

According to the invention, the faces of the surface of the p-type thermoelectric conversion element other than the faces that are to face the electrodes, and the faces of the surface of the n-type thermoelectric conversion element other than the faces that are to be face the electrodes, are covered by an insulating film while the p-type thermoelectric conversion element and the n-type thermoelectric conversion element are stacked via the two insulating films, and therefore the insulating reliability between the p-type thermoelectric conversion element and the n-type thermoelectric conversion element is particularly excellent and it is possible to provide a high-density thermoelectric conversion module.

### Advantageous Effects of Invention

According to the invention it is possible to provide a method for manufacturing a thermoelectric conversion module that can conveniently yield a thermoelectric conversion module with a high insulating property and high density without requiring positioning of the thermoelectric conversion elements, as well as a thermoelectric conversion module manufactured by the method.

### BRIEF DESCRIPTION OF DRAWINGS

FIG. 1 is a schematic diagram showing an example of a method for manufacturing a thermoelectric conversion module 11 according to a first embodiment of the invention.

FIG. 2 is a cross-sectional view of an example of a thermoelectric conversion module 1 according to an embodiment of the invention.

FIG. 3 is a schematic diagram showing an example of a method for manufacturing a thermoelectric conversion module 11 according to a second embodiment of the invention.

FIG. 4 is a cross-sectional view showing another example of a thermoelectric conversion module 1 according to an embodiment of the invention.

### DESCRIPTION OF EMBODIMENTS

Preferred embodiments according to the present invention will be explained in detail, with reference to the attached drawings. In the description for the drawings, the same reference numerals will be put on the same or corresponding element, and overlapping descriptions will be omitted. In addition, a dimensional ratio in each drawing does not necessarily match an actual dimensional ratio.

Methods for manufacturing a thermoelectric conversion module according to the embodiments will be explained first.

### (Method for Manufacturing Thermoelectric Conversion Module According to First Embodiment)

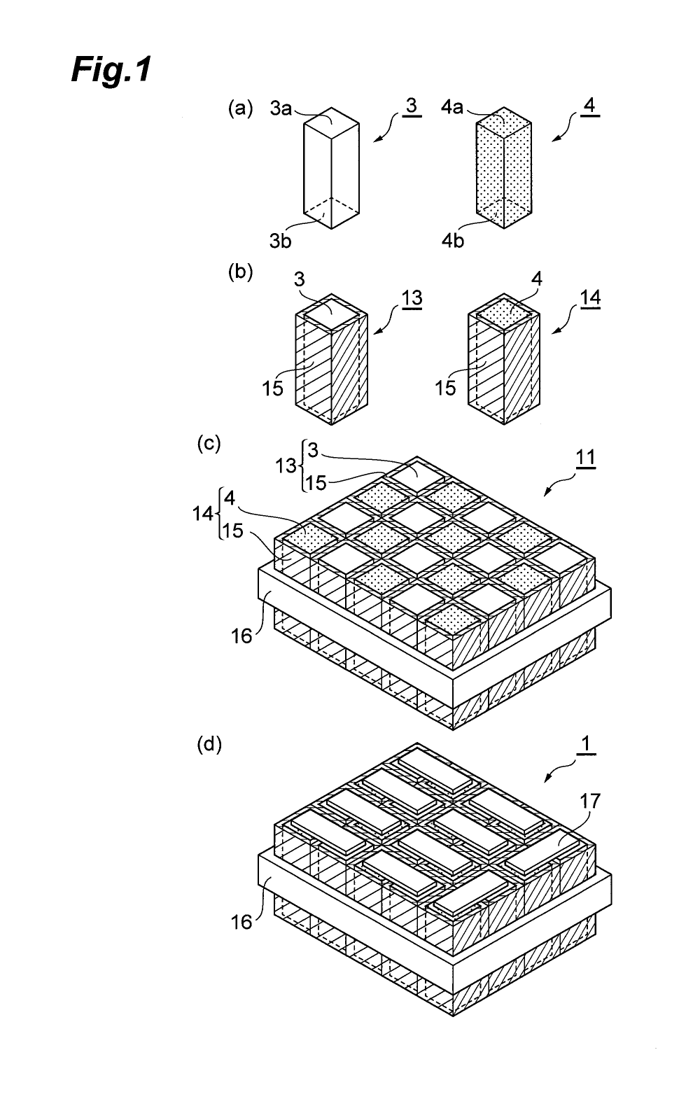

A method for manufacturing a thermoelectric conversion module according to the first embodiment will be explained first. FIG. 1 schematically shows an example of a method for manufacturing a thermoelectric conversion module according to the first embodiment. The method for manufacturing a thermoelectric conversion module according to the first embodiment comprises (a) a step of preparing thermoelectric conversion elements, (b) a step of covering the thermoelectric conversion elements with an insulating film, (c) a step of stacking the thermoelectric conversion elements and (d) a step of bonding the electrodes.

(a) Step of Preparing Thermoelectric Conversion Elements

First, rectangular parallelepiped p-type thermoelectric conversion elements 3 and n-type thermoelectric conversion elements 4 are prepared as shown in FIG. 1(a), for example. The shapes of the thermoelectric conversion elements are not particularly restricted, and may be hexahedral such as rectangular parallelepiped, or hexagonal columnar, circular columnar or discoid. The material of each of the thermoelectric conversion elements is not particularly restricted so long as it has a p-type semiconductor quality or an n-type semiconductor quality, and various materials such as metals or metal oxides may be used.

The method for fabricating the p-type thermoelectric conversion elements 3 and the n-type thermoelectric conversion elements 4 differs depending on the material composing the thermoelectric conversion elements, and for example, if the constituent material is a metal, the bulk metal may be cut into the desired shapes to form the thermoelectric conversion elements. If the constituent material is a metal oxide, for example, a compound containing a metal element which is to compose the metal oxide may be mixed and sintered in an oxygen-containing atmosphere, and the obtained sintered body may be cut and then formed into the desired shapes to obtain thermoelectric conversion elements.

Materials for the p-type thermoelectric conversion element 3 and the n-type thermoelectric conversion element 4 include the following. Examples of materials for the p-type thermoelectric conversion element 3 include: mixed metal oxides such as NaₓCoO₂ (0<x<1) and Ca₃CO₄O₉, silicides such as MnSi_{1.73}, Fe₁₋ₓMnₓSi₂, Si_{0.8}Ge_{0.2}:B (B-doped Si_{0.8}Ge_{0.2}) and βFeSi₂, skutterudites such as CoSb₃, FeSb₃, RFe₃CoSb₁₂ (where R represents La, Ce or Yb), Te-containing alloys such as BiTeSb, PbTeSb, Bi₂Te₃, Sb₂Te₃ and PbTe, and Zn₄Sb₃.

Examples of materials for the n-type thermoelectric conversion element 4 include: mixed metal oxides such as SrTiO₃, Zn₁₋ₓAlₓO, CaMnO₃, LaNiO₃, BaTiO₃ and Ti₁₋ₓNbₓO, silicides such as Mg₂Si, Fe₁₋ₓCoₓSi₂, Si_{0.8}Ge_{0.2}:P (P-doped Si_{0.8}Ge_{0.2}) and β-FeSi₂, skutterudites such as CoSb₃, clathrate compounds such as Ba₈Al₁₂Si₃₀, Ba₈AlₓSi₄₆₋ₓ, Ba₈Al₁₂Ge₃₀, Ba₈AlₓGe₄₆₋ₓ, and Ba₈GaₓGe₄₆, boron compounds such as CaB₆, SrB₆, BaB₆ and CeB₆, Te-containing alloys such as BiTeSb, PbTeSb, Bi₂Te₃, Sb₂Te₃ and PbTe, and Zn₄Sb₃.

Considering that thermoelectric conversion modules may be used at temperatures of 300° C. or higher, the p-type thermoelectric conversion element 3 and n-type thermoelectric conversion element 4 preferably comprise a metal oxide or a silicide as the main component in the materials, from the viewpoint of heat resistance and oxidation resistance. Among metal oxides, the material of the p-type thermoelectric conversion element 3 is preferably Ca₃CO₄O₉ and the material of the n-type thermoelectric conversion element 4 is preferably CaMnO₃. Ca₃CO₄O₉ and CaMnO₃ have particularly excellent oxidation resistance in high-temperature air atmospheres, as well as high thermoelectric conversion performance.

The p-type thermoelectric conversion elements 3 and the n-type thermoelectric conversion elements 4 may have metal layers on each of the faces 3a, 3b and the faces 4a, 4b. Such metal layers are sometimes provided to increase adhesion with the binder which bonds the electrodes as described hereunder to the thermoelectric conversion elements.

(b) Step of Covering Thermoelectric Conversion Elements with Insulating Film

Next, the surface of each of the p-type thermoelectric conversion elements 3 and the n-type thermoelectric conversion elements 4 is covered with an insulating film 15. Specifically, in the p-type thermoelectric conversion element 3 and the n-type thermoelectric conversion element 4 shown in FIG. 1(a), at least the faces of each element surface other than the faces 3a, 3b and 4a, 4b that are to face the electrodes, are covered with an insulating film 15 as shown in FIG. 1(b).

The method of covering the p-type thermoelectric conversion element 3 and the n-type thermoelectric conversion element 4 with the insulating film 15 includes a method in which a composition to form the insulating film 15 is applied onto the faces other than the faces 3a, 3b and the faces 4a, 4b, or a method in which the faces 3a, 3b of the p-type thermoelectric conversion element 3 and the faces 4a, 4b of the p-type thermoelectric conversion element 4 are first covered with an easily detachable cover, and then the thermoelectric conversion elements 3, 4 are dipped into a bath of the composition to form the insulating film 15, so that the composition to form the insulating film 15 is formed on the surfaces other than the faces 3a, 3b of the thermoelectric conversion element 3 and the faces 4a, 4b of the thermoelectric conversion element 4, after which the covers covering the faces 3a, 3b and the faces 4a, 4b are removed.

The compositions to form the insulating film 15 include: a composition to form an inorganic insulator film such as an alumina-based insulator, an alumina/silicon carbide (SiC)-based insulator or a silica-based insulator; or a composition to form an organic insulator film, such as an epoxy-based insulator. Considering that thermoelectric conversion modules are used at temperatures of 300° C. or higher, a composition to form an inorganic insulator film is preferable from the viewpoint of heat resistance. Examples of compositions to form alumina-based insulator films include: BETACK (trade name of Telnik Industrial Co., Ltd.), compositions to form alumina/silicon carbide (SiC)-based insulator films include SP COAT (trade name of Ceramic Coat Co., Ltd.), and compositions to form silica-based insulator films include SILICA COAT (trade name of Exousia, Inc.). The inorganic adhesives mentioned for the anchor means 16 described hereunder may also be used.

The thickness of the insulating film 15 is preferably around from 20 μm to 1 mm and more preferably around from 100 μm to 0.5 mm. Formation of an insulating film 15 exceeding 1 mm is not preferred in consideration of reduced element density. Suitable film thicknesses for the insulating film 15 formed with the aforementioned compositions for formation of inorganic insulator films are around from 0.1 to 1 mm for BETACK, around from 0.05 to 0.1 mm for SP COAT and around from 0.01 to 0.05 mm for SILICA COAT.

(c) Step of Stacking Thermoelectric Conversion Elements

Next, as shown in FIG. 1(c), the p-type thermoelectric conversion elements 13 having the insulating film 15 formed on the faces other than the faces 3a, 3b and the n-type thermoelectric conversion elements 14 having the insulating film 15 formed on the faces other than the faces 4a, 4b, are stacked respectively so that their insulating films 15 are facing each other. Specifically, the elements 13 and elements 14 are stacked into the overall arrangement of an alternating matrix wherein, for each of the adjacent pair of an element 13 and an element 14, one face among the faces of the element 13 on which the insulating film has been formed and one face among the faces of the element 14 on which the insulating film has been formed are stacked together via the insulating films 15 of the respective elements. That is, at least faces of the surface of each p-type thermoelectric conversion element other than the faces that are to face the electrodes, and at least the faces of the surface of each n-type thermoelectric conversion element other than the faces that are to face the electrodes, are stacked via the insulating films.

After the plurality of p-type thermoelectric conversion elements 13 and the plurality of n-type thermoelectric conversion elements 14 have been alternately arranged as described above, the outer periphery of the resulting thermoelectric conversion block 11 is preferably anchored with anchor means 16, as shown in FIG. 1(c). Examples of the anchor means 16 include a support frame, inorganic adhesive, or the like. The material of the support frame used may be one or more ceramic materials such as zirconia, cordierite, alumina, mullite, magnesia, silica, calcia or the like. The examples of the inorganic adhesive includes an inorganic adhesive composed mainly of silica-alumina, silica, zirconia or alumina (SUMICERAM S, trade name of Asahi Chemical Co., Ltd.), or an inorganic adhesive composed mainly of zirconia-silica (ARON CERAMIC, trade name of Toagosei Co., Ltd.).

(d) Step of Bonding Electrodes

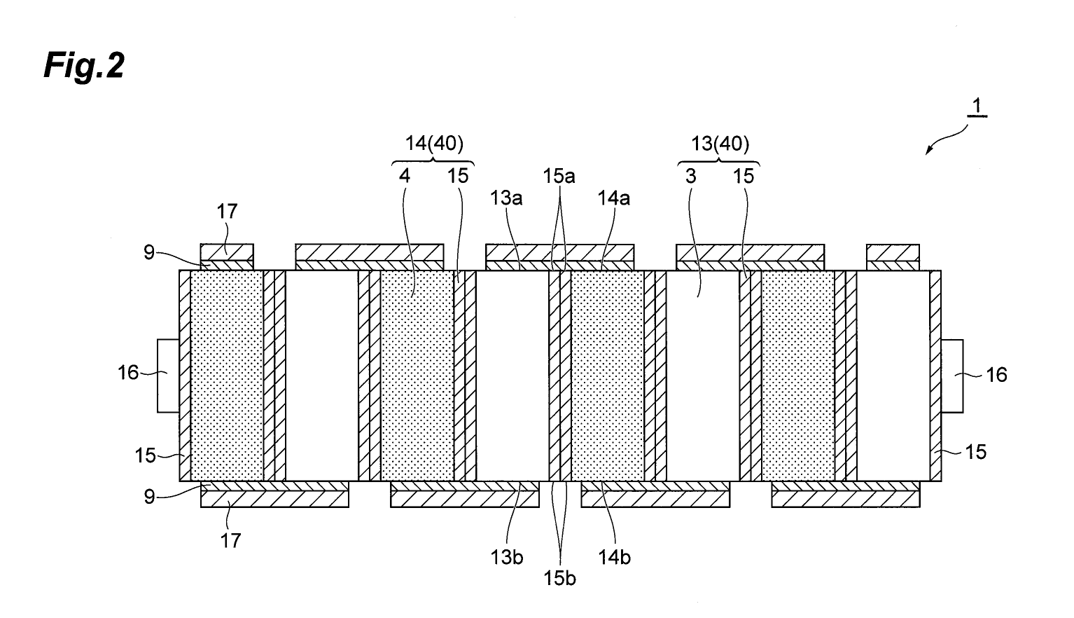

Electrodes 17 are bonded to one end faces of the mutually adjacent p-type thermoelectric conversion elements 13 and the n-type thermoelectric conversion elements 14, among the plurality of p-type thermoelectric conversion elements 13 and the plurality of n-type thermoelectric conversion elements 14 which have been stacked with each other, as shown in FIG. 1(d). This accomplishes electrical connection between the plurality of p-type thermoelectric conversion elements 13 and the plurality of n-type thermoelectric conversion elements 14. FIG. 2 shows a cross-sectional view of a thermoelectric conversion module 1 obtained by this process.

Examples of the electrodes 17 include metal sheets or the like. The metal sheets or other material used are preferably bonded to the faces 13a, 13b of the p-type thermoelectric conversion elements 13 and the faces 14a, 14b of the n-type thermoelectric conversion elements 14 using a binder 9, as shown in FIG. 2, for example. The binder 9 is formed on the surfaces of the electrodes 17 or on the surfaces of the thermoelectric conversion elements 40 facing the electrodes 17, but it may be formed not only the faces 13a, 13b and the faces 14a, 14b, but also on the face 15a of the insulating film 15 sandwiched between the faces 13a, 14a, and on the faces 15b of the insulating film 15 sandwiched between the faces 13b, 14b. This will allow a skeleton-type thermoelectric conversion module 1 to be obtained wherein the plurality of p-type thermoelectric conversion elements 13 and the plurality of n-type thermoelectric conversion elements 14 are electrically connected in series.

The material for the first electrodes 17 is not particularly restricted so long as it is conductive, but from the viewpoint of heat resistance and corrosion resistance of the electrodes and improvement of adhesion property onto the thermoelectric conversion elements 40, it is preferably a metal whose main component is one or more elements selected from the group consisting of titanium, vanadium, chromium, manganese, iron, cobalt, nickel, copper, molybdenum, silver, palladium, gold, tungsten and aluminum. Here, “main component” means a component present at 50% by volume or greater in the electrode material.

The binder 9 includes AuSn-based solder, silver paste, a wax material, or the like. The binder 9 may be formed as a thin-film by a method such as sputtering, vapor deposition, application, screen printing, plating or thermal spraying.

This method for manufacturing a thermoelectric conversion module does not require positioning of the p-type thermoelectric conversion elements and the n-type thermoelectric conversion elements, and is therefore more convenient than conventional methods for manufacturing thermoelectric conversion modules. In addition, the thermoelectric conversion module obtained by the manufacturing method ensures adequate insulation between the elements with the insulating films 15, and therefore permits high-density placement of the thermoelectric conversion elements, downsizing, and high output. A thermoelectric conversion module 1 having an insulating film 15 on both the p-type thermoelectric conversion elements 3 and the n-type thermoelectric conversion elements 4 has very high insulating reliability between elements.

A method for manufacturing a thermoelectric conversion module according to the second embodiment will now be described.

### (Method for Manufacturing Thermoelectric Conversion Module According to Second Embodiment)

In the method for manufacturing a thermoelectric conversion module according to the second embodiment, the entire surface of the thermoelectric conversion element 3 and the entire surface of the thermoelectric conversion element 4 are covered with the insulating film 15 in the (b) step of covering the thermoelectric conversion elements with an insulating film. The method for manufacturing a thermoelectric conversion module of this embodiment also comprises a step of removing the insulating film on the faces of the thermoelectric conversion elements that are to face the electrodes, after the (c) step of stacking the thermoelectric conversion elements.

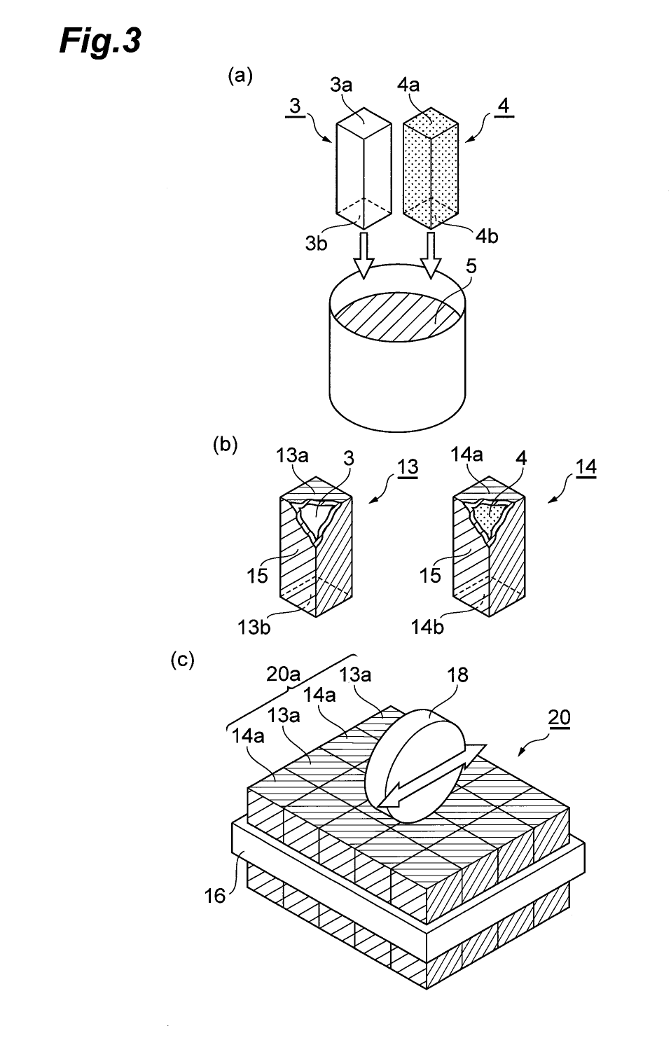

First, rectangular parallelepiped p-type thermoelectric conversion elements 3 and parallelepiped n-type thermoelectric conversion elements 4 are prepared as shown in FIG. 3(a), for example. The thermoelectric conversion elements 3, 4 for this embodiment have the insulating film 15 formed over the entire surfaces of the thermoelectric conversion elements 3, 4, and therefore they preferably have shapes that allow the faces of the thermoelectric conversion elements 3, 4 that are to face the electrodes to be ascertained even after the entire surfaces of the thermoelectric conversion elements 3, 4 have been covered by the insulating film 15. For example, when the thermoelectric conversion elements 3, 4 are rectangular parallelepiped thermoelectric conversion elements as shown in FIG. 3(a), the shapes of the thermoelectric conversion elements 3, 4 may be established so that the faces 3a, 3b and 4a, 4b of smallest area are the areas to face the electrodes.

Next, the thermoelectric conversion elements 3, 4 are dipped in a bath 5 of the composition to form the insulating film 15, to form an insulating film 15 on the entire surfaces of the thermoelectric conversion elements 3, 4, as shown in FIG. 3(b). Then, as shown in FIG. 3(c), for the p-type thermoelectric conversion elements 13 and the n-type thermoelectric conversion elements 14 on which the insulating film 15 has been formed on the entire surface similar to step (c) of the first embodiment described above, the faces of the p-type thermoelectric conversion elements 13 other than the faces 13a, 13b that are to face the electrodes and the faces of the n-type thermoelectric conversion elements 14 other than the faces 14a, 14b that are to face the electrode are stacked via the insulating films 15. The p-type thermoelectric conversion elements 13 and the n-type thermoelectric conversion elements 14 are thus arranged in an alternating fashion. It is preferable that the plurality of p-type thermoelectric conversion elements 13 and the plurality of n-type thermoelectric conversion elements 14 which have been stacked with each other be integrally anchored using the aforementioned anchor means 16 before removing the insulating film 15 formed on the faces 13a, 13b and faces 14a, 14b, such as shown in FIG. 3(c), for example, to produce a thermoelectric conversion block 20.

The plurality of p-type thermoelectric conversion elements 13 and the plurality of n-type thermoelectric conversion elements 14 which have been stacked with each other are subjected to grind and removal of the insulating film 15 formed on the faces 13a, 13b of the p-type thermoelectric conversion elements 13 that are to face the electrodes, and the insulating film 15 formed on the faces 14a, 14b of the n-type thermoelectric conversion elements 14 that are to face the electrodes. For example, as shown in FIG. 3(c), the insulating film 15 covering the faces 20a, 20b (not shown) of the thermoelectric conversion block 20 that are to face the electrodes may be removed using grind means 18. The grind means is not particularly restricted, and for example, it includes manual grind using abrasive paper, or automatic polishing using a surface grinding apparatus. A thermoelectric conversion block 11 such as shown in FIG. 1(c) is thus obtained.

By this step, it is possible in one operation to efficiently remove the insulating film 15 formed on the faces 13a, 13b and faces 14a, 14b of the plurality of p-type thermoelectric conversion elements 13 and the plurality of n-type thermoelectric conversion elements 14 which have been stacked with each other. In particular, it is possible to sufficiently anchor the plurality of p-type thermoelectric conversion elements 13 and the plurality of n-type thermoelectric conversion elements 14 which have been stacked with each other for easy grind, by integrally anchoring, using anchor means 16, the plurality of p-type thermoelectric conversion elements 13 and the plurality of n-type thermoelectric conversion elements 14 which have been stacked with each other to produce a thermoelectric conversion block 20.

Next, electrodes 17 such as shown in FIG. 1(d) are bonded to the thermoelectric conversion block 11 in the same manner as the (d) step of bonding the electrodes in the first embodiment described above. A thermoelectric conversion module 1 such as shown in FIG. 2 can thus be obtained by the method for manufacturing a thermoelectric conversion module of this embodiment as well.

According to this embodiment, an insulating film on the surfaces of the thermoelectric conversion elements can be formed by simply dipping the thermoelectric conversion element into the composition to form the insulating film, which is therefore convenient. The step of stacking the p-type thermoelectric conversion elements 13 and the n-type thermoelectric conversion elements 14 with each other and removing the insulating film facing the electrodes is also relatively convenient since the face of each thermoelectric conversion element to face an electrode is ground once for removal of the insulating film 15. It is therefore preferred because the step is simplified overall, compared to the manufacturing method of the first embodiment in which the insulating film is formed on the surface of each thermoelectric conversion element so that the faces that are to face the electrodes are not covered by the insulating film.

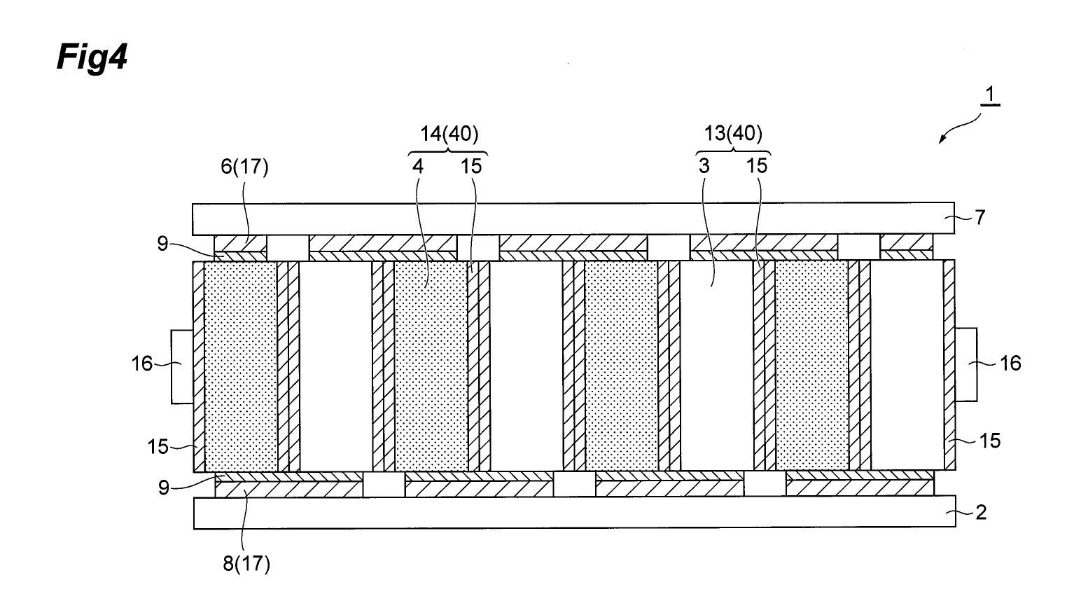

The thermoelectric conversion module obtained by the method for manufacturing a thermoelectric conversion module of this embodiment may be a skeleton-type as shown in FIG. 2, or a substrate-attached type as shown in FIG. 4.

FIG. 4 is a cross-sectional view of another example of a thermoelectric conversion module 1 manufactured by the method for manufacturing a thermoelectric conversion module according to the first and second embodiments. This thermoelectric conversion module 1 has substrates formed on the surfaces of the electrodes 17 of the skeleton-type thermoelectric conversion module described above. This thermoelectric conversion module 1 comprises a first substrate 2, first electrodes 8, thermoelectric conversion elements 40, second electrodes 6 and a second substrate 7. The p-type thermoelectric conversion elements 3 and the n-type thermoelectric conversion elements 4 are alternately situated between the first substrate 2 and second substrate 7, via their respective insulating films 15. The thermoelectric conversion module 1 does not necessarily need to have both the first substrate 2 and the second substrate 7, any it may have either one alone.

The first substrate 2 and the second substrate 7 have rectangular shapes, for example, and are electrically insulating and thermally conductive, while covering one end of the plurality of thermoelectric conversion elements 40. Examples of the materials of the substrates include alumina, aluminum nitride, magnesia, silicon carbide, zirconia, mullite or the like.

The first electrodes 8 and the second electrodes 6 may be formed beforehand on the first substrate 2 and the second substrate 7. The electrodes may be formed on prescribed locations on the substrates by sputtering, vapor deposition, application, screen printing, plating, thermal spraying or the like. Also, a metal sheet may be bonded onto each substrate by soldering, brazing or the like. The electrode material includes one of those mentioned above for the previous embodiments.

Such a substrate-attached thermoelectric conversion module 1 exhibits an effect similar to the thermoelectric conversion module described above.

The method for manufacturing a thermoelectric conversion module according to the invention, and a thermoelectric conversion module obtained by the manufacturing method, are not limited to the embodiments described above, and many modified forms thereof are possible. For example, in the embodiment described above, both of the p-type thermoelectric conversion element 3 and the n-type thermoelectric conversion element 4 are covered by the insulating film 15, but the invention can be carried out by covering either type of thermoelectric conversion element of the p-type thermoelectric conversion element 3 and the n-type thermoelectric conversion element 4, with the insulating film 15.

Also, the second embodiment described above had, in the step of grinding and removing the insulating film, the plurality of p-type thermoelectric conversion elements 13 and the plurality of n-type thermoelectric conversion elements 14 which were stacked with each other so that the p-type thermoelectric conversion elements 13 and the n-type thermoelectric conversion elements 14 were arranged in an alternating manner, and then the insulating film 15 formed on the faces 13a, 13b and the faces 14a, 14b was ground and removed, but alternatively, first the plurality of p-type thermoelectric conversion elements 13 may be stacked and the insulating film 15 having been formed on the faces 13a, 13b may be ground and removed, and separately the plurality of n-type thermoelectric conversion elements 14 may be stacked and the insulating film 15 having been formed on the faces 14a, 14b may be ground and removed, after which the plurality of p-type thermoelectric conversion elements 13 from which the insulating film 15 having been formed on the faces 13a, 13b are removed and the plurality of p-type thermoelectric conversion elements 14 from which the insulating film 15 having been formed on the faces 14a, 14b are removed, may be stacked with each other in an alternating fashion, and the electrodes bonded therewith to produce a thermoelectric conversion module.

### EXPLANATION OF SYMBOLS

1: Thermoelectric conversion module, 2: first substrate, 3,13: p-type thermoelectric conversion elements, 4,14: n-type thermoelectric conversion elements, 6: second electrode, 7: second substrate, 8: first electrode, 9: binder, 11, 20: thermoelectric conversion blocks, 15: insulating film, 16: anchor means, 17: electrode, 3a, 3b: faces of p-type thermoelectric conversion element surfaces that are to face the electrodes, 4a, 4b: faces of n-type thermoelectric conversion element surfaces that are to face the electrodes, 20a: face of thermoelectric conversion block that is to face the electrodes, 40: thermoelectric conversion element.

1. A method for manufacturing a thermoelectric conversion module comprising:
a covering step of covering, with an insulating film, at least faces of the surface of a p-type thermoelectric conversion element other than faces that are to face electrodes, and/or at least faces of the surface of an n-type thermoelectric conversion element other than faces that are to face electrodes, and
a stacking step of stacking the faces of the surface of the p-type thermoelectric conversion element other than the faces that are to face the electrodes, and the faces of the surface of the n-type thermoelectric conversion element other than the faces that are to face the electrodes via the insulating film.

2. The method for manufacturing a thermoelectric conversion module according to claim 1, wherein
in the covering step, the entire surface of the p-type thermoelectric conversion element and/or the entire surface of the n-type thermoelectric conversion element are covered with the insulating film, and
the method further comprises an insulating film removal step of removing the insulating film by subjecting the p-type thermoelectric conversion element and the n-type thermoelectric conversion element stacked in the stacking step to grind of the faces of the surface of the p-type thermoelectric conversion element that are to face the electrodes and/or the faces of the surface of the n-type thermoelectric conversion element that are to face the electrodes.

3. The method for manufacturing a thermoelectric conversion module according to claim 2, which comprises, prior to the insulating film removal step,
a step of integrally anchoring the p-type thermoelectric conversion element and the n-type thermoelectric conversion element stacked in the stacking step to obtain a thermoelectric conversion block.

4. A thermoelectric conversion module comprising:
a p-type thermoelectric conversion element,
an n-type thermoelectric conversion element,
electrodes that electrically connect the p-type thermoelectric conversion element to the n-type thermoelectric conversion element,
an insulating film covering the faces of the surface of the p-type thermoelectric conversion element other than the faces facing the electrodes, and
an insulating film covering the faces of the surface of the n-type thermoelectric conversion element other than the faces facing the electrodes, wherein
the p-type thermoelectric conversion element and the n-type thermoelectric conversion element are stacked via the two insulating films.
